(19) United States
(12) Patent Application Publication
(10) Pub. No.: US 2026/0313826 A1
(43) Pub. Date: Oct. 8, 2026

(54) NESTED CONTAINER AND NESTED CONTAINER SERVER APPARATUS

(71) Applicant: CANAAN CREATIVE CO.,LTD, Beijing (CN)

(72) Inventors: Guanchao Zhao, Beijing (CN); Nan Li, Beijing (CN); Shishuang He, Beijing (CN); Zonghai Chen, Beijing (CN); Xiaogang Sun, Beijing (CN); Xiaoye Zhao, Beijing (CN); He Ying, Beijing (CN); Nangeng Zhang, Beijing (CN)

(21) Appl. No.: 19/479,443

(22) PCT Filed: Mar. 7, 2024
(86) PCT No.: PCT/CN2024/080553

§ 371 Date: Oct. 28, 2025

(30) Foreign Application Priority Data
Apr. 28, 2023 (CN) 202321024380.3
Apr. 28, 2023 (CN) 202321025322.2
May 17, 2023 (CN) 202321197000.6

(51) Int. Cl. H05K 7/14

(52) U.S. Cl. CPC H05K 7/1497

(57) ABSTRACT

A nested container (1) and a nested container server apparatus. The nested container comprises a box body (100), a rack (200) and an electric control system, the rack (200) and the electric control system being separately fixed in the box body (100). The size of the outer contour of the box body (100) is smaller than the size of the inner space of a standard container, and the box body (100) can be integrally loaded in the standard container, thereby improving safety during the transportation process and reducing losses.

### CROSS-REFERENCE TO RELATED APPLICATIONS

The present application claims priority to Chinese Patent Application No. 202321025322.2 filed on Apr. 28, 2023, priority to Chinese Patent Application No. 202321024380.3 filed on Apr. 28, 2023, and priority to Chinese Patent Application No. 202321197000.6 filed on May 17, 2023, which are incorporated herein by reference for all purposes as if fully set forth herein.

### TECHNICAL FIELD

The present application relates to the field of computing apparatus, and specifically to a nested container and a nested container server apparatus.

### BACKGROUND

A container server cluster refers to a server cluster formed by integrating a plurality of servers into a container or modular cabinet, which can be rapidly deployed and relocated. This approach can improve the density and efficiency of the servers, meet the rapidly growing demand for data processing, reduce energy consumption and costs, and provide flexibility and scalability.

The technical problem that needs to be solved by those skilled in the art is how to maintain the safety and stability of the container server cluster in a long-distance transportation process while maximizing integration and reduce damage in the transportation process.

### SUMMARY

The purpose of the present application is to provide a nested container, which is nested within a standard container for long-distance transportation, ensuring the safety and stability of the transportation while maximizing integration, and greatly reducing the damage rate during the transportation.

Another purpose of the present application is to provide a nested container server apparatus including the aforementioned nested container.

In order to achieve the above purposes, a nested container of the present application includes a container body, wherein an outer contour dimension of the container body is smaller than an inner space dimension of a standard container, and the container body is configured to be entirely loaded into the standard container. The container referred to in the present application may be regarded as a dedicated container, wherein the nested container includes the container body, a rack, and an electric control system, the rack and the electric control system are respectively fixed within the container body, an outer contour dimension of the container body is smaller than an inner space dimension of the standard container, and the container body is configured to be entirely loaded into the standard container. The nested container of the present utility model combines design compactness, high operational efficiency, high maintenance performance, high structural strength and high resistance to vibration and impact. Meanwhile, by designing the outer dimension of length, width and height of the container body to be slightly smaller than the inner space dimension of the standard container, the nested container of the present utility model is capable of being entirely loaded into the standard container, thereby improving safety during the transportation and reducing losses.

Regarding the aforementioned nested container, when the container body is loaded within the standard container, a first gap and/or a second gap are respectively present between left and right side walls of the container body along a length direction and left and right inner walls of the standard container along the length direction. Preferably, a sum of the first gap and the second gap is 90±20 mm.

Regarding the aforementioned nested container, a third gap and/or a fourth gap are respectively present between front and rear side walls of the container body along a width direction and front and rear inner walls of the standard container along the width direction. Preferably, a sum of the third gap and the fourth gap is 90±20 mm.

Regarding the aforementioned nested container, a fifth gap is present between a top wall of the container body and a top inner wall of the standard container. Preferably, the fifth gap is 40±10 mm.

The first gap to the fifth gap are configured to provide a relative moving distance when the nested container is loaded into the standard container, and to provide assembly tolerance for manufacturing errors, movement shaking, and minor deformations, so as to prevent the nested container from failing to enter the standard container, or from being stuck and failing to relatively move during loading.

Regarding the above nested container, it further includes a buffer member disposed in at least one of the first gap to the fifth gap.

By filling the first gap to the fifth gap with the buffer member, shaking and collision can be further prevented.

The above buffer member includes a wooden structural member disposed at a bottom of at least one of the first gap to the fifth gap. It is convenient to operate and has a good buffering effect.

The above buffer member includes a corner protection structural member mounted on a corner member of the container body. The corner protection structural member is, for example, a wooden material member, a plastic material member, a foam material member or a rubber material member. The corner protection structural member buffers the corner member part of the container body, reducing a force generated when the corner member collides with an interior of the standard container, thereby ensuring safety of the container body.

The above buffer member includes a ridge structural member mounted to at least one of a corner post, a bottom side beam, and a top side beam of the container body. The ridge structural member is, for example, in an L-shape, and is a wooden material member, a plastic material member, a foam material member or a rubber material member. The ridge structural member buffers the side beam parts of the container body, reducing a force generated when the side beams collide with the interior of the standard container, thereby ensuring safety of the container body.

The above buffer member includes a foam member filled in at least one of the first gap to the fifth gap. The foam member is configured to form a buffer between wall faces of the container body and the standard container.

The above buffer members may be used in combination to respectively provide buffering protection or multiple protection for different parts of the container body.

Regarding the above nested container, it further includes a limiting member disposed in at least one of the first gap to the fifth gap, configured to limit a position of the nested container in the standard container, reducing a possibility of collision between the nested container and the standard container.

Regarding the above nested container, the limiting member includes left and right side limiting structural members disposed in the middle of the first gap and/or the second gap along the length direction of the standard container. By disposing the left and right side limiting structural members, the first gap and the second gap are defined to remain equal when the nested container is loaded within the standard container.

Regarding the above nested container, the limiting member includes front and rear side limiting structural members disposed in the third gap or the fourth gap away from an entrance of the standard container. By disposing the front and rear side limiting structural members, the third gap and the fourth gap are defined to remain equal when the nested container is loaded within the standard container.

Regarding the above nested container, a movement assisting accessory is disposed between a bottom of the container body and a bottom of the standard container to facilitate movement, reducing friction between the nested container and the standard container during loading or unloading, thereby reducing vibration and wear.

Regarding the above nested container, the movement assisting accessory includes a roller means connected to the bottom of the container body. The roller means is connected to a bottom of the corner member of the container body, or the roller means is connected to the bottom side beam and/or the bottom of the corner member of the container body. The roller means is, for example, a metal wheel mounted at the bottom of the container, enabling the container can move on the ground. The container wheel may be fixed or rotatable, so as to facilitate adjustment to a direction of the container.

Regarding the above nested container, the movement assisting accessory includes a slide rail means connected to the bottom of the container body or to a bottom plate of the standard container. The slide rail means is generally made of metal, allowing the container to slide along the slide rail while withstanding the weight and friction of the container, thereby facilitating movement of the container.

Regarding the above nested container, the movement assisting accessory includes a slide plate means connected to the bottom of the container body or to the bottom plate of the standard container. The slide plate is mounted between the bottom of the standard container and the bottom of the nested container. The slide plate means is made of, for example, a metal sheet, allowing relative sliding to generate between the nested container and the standard container, thereby reducing friction when the container moves.

Regarding the above nested container, at least one container body is loaded within the standard container along the length direction of the container body. In other words, a plurality of nested containers can be loaded within one standard container.

Regarding the above nested container, the container body includes a corner member. The nested container of the present application further includes a tensioning member connected between the corner member and the inner wall of the standard container, configured to lock between the nested container and the standard container.

Regarding the above nested container, the electric control system includes a power distribution cabinet. Racks are symmetrically disposed on both sides of the power distribution cabinet. By providing a symmetrical configuration of the racks on both sides of the power distribution cabinet, the same number of servers of the same specifications can be arranged on the racks, so that power lines leading out of the power distribution cabinet to both ends are evenly distributed and clearly routed. This makes it easy for staff to manage and maintain, and can avoid troubles caused by too many and too long power lines and complex wiring redundancy due to single-side cabling, thereby reducing maintenance manpower and apparatus costs. Moreover, it can further ensure the overall counterweight balance of the container and increase the overall reliability of the apparatus.

Regarding the above nested container, the container body includes a first side heat dissipation long side and a second side heat dissipation long side oppositely disposed. The first side heat dissipation long side is provided with a dustproof mesh and/or a louver, and the second side heat dissipation long side is provided with a cooling structure. The present application utilizes air cooling for heat dissipation. Air cooling is a high-efficiency and low-consumption heat dissipation method characterized by simple structure, low cost, and excellent heat dissipation effect.

Regarding the nested container, the cooling structure includes a fan and a fan mounting frame. The fan is mounted to the container body via the fan mounting frame.

Regarding the above nested container, the fan mounting frame includes a connection frame connected to the container body and a support frame detachably connected to an inner side or an outer side of the connection frame via a plurality of fasteners. The fan is disposed on the support frame. The fan is connected to an inner side or an outer side of the connection frame via the support frame and thus can be placed on an inner side or outer side of the container body, achieving switching between inside and outside placement of the fan to meet different heat dissipation needs in different regions.

Regarding the above nested container, the support frame includes a fixing portion configured to detachably connect the connection frame via the fastener and a support portion configured to support the fan. The support frame includes a limiting portion configured to limit displacement of the fan. The support frame is made from a metal sheet that is bent and processed to form the fixing portion, the support portion and the limiting portion. It is simple in processing and firm in structure.

Regarding the above nested container, the connection frame is further partially connected to at least one of the top side beam, the bottom side beam, and the corner post of the container body. The top side beam, bottom side beam and corner post structures of the container are utilized to mount the connection frame, making the structure firm and not easy to deform.

Regarding the above nested container, a position on the first side heat dissipation long side corresponding to the power distribution cabinet is provided with a protective wall, and a position on the first side heat dissipation long side corresponding to the rack is provided with a dustproof mesh and/or a louver. The protective wall is made of, for example, a steel plate and the corner post. Parts of the protective wall can be reinforced with transverse and longitudinal stiffeners to increase the overall strength of the container body, enhance the resistance of the container body to deformation and extrusion, and reduce the likelihood of damage during loading, unloading and transportation.

Regarding the above nested container, it further includes a water curtain cooling structure and a water curtain storage structure configured to store the water curtain cooling structure. The water curtain storage structure is located within the container body. It further includes an accessory box fixed within the container body. The water curtain storage structure and the accessory box are disposed within the container body. During transportation, the accessory facilities on the outer side of the container body are removed and fixed within the container body to ensure the minimized dimension of the container body.

The nested container server apparatus of the present application includes a plurality of servers, wherein the nested container server apparatus further includes the aforementioned nested container, and the servers are arranged and disposed on the rack and connected to the electric control system.

Regarding the above nested container server apparatus, the top of the rack has a topmost-layer partition plate and an extension baffle extending horizontally from the topmost-layer partition plate. The servers are disposed on the topmost-layer partition plate and/or the extension baffle. By disposing the extension baffle connected to an outer side of the uppermost-layer partition plate along the width direction of the container body, the present application achieves an increased length of the partition plate at the uppermost layer of the rack along the width direction of the container body, and an increased number of integrated servers, which can improve the computing power of the apparatus.

Regarding the above nested container server apparatus, it further includes a top-layer apparatus status feedback means configured to feed back an operating status of the servers on the topmost-layer partition plate and/or the extension baffle.

Regarding the above nested container server apparatus, the top-layer apparatus status feedback means is a reflective mirror observation means. The present application utilizes a reflective mirror as the top-layer apparatus status feedback means, and can achieve real-time monitoring of the server status by means of a status indicator light of the server itself without investing any software or hardware in the server. The reflective mirror observation means may be single or multiple, providing real-time feedback on the operating status of each server in real time. This enables the staff to respond promptly, ensuring the operational efficiency of the apparatus.

Regarding the above nested container server apparatus, the reflective mirror observation means includes a plurality of feedback areas, each corresponding to at least one server disposed on the topmost-layer partition plate and/or the extension baffle. Each of the feedback areas corresponds to at least one server disposed on the topmost-layer hierarchical partition, and feeds back an operating status of the server in real time, which facilitates timely processing by the staff and ensures the operational efficiency of the apparatus.

The present application will be described in detail below in conjunction with the drawings and specific embodiments, but is not intended to limit the present application.

### BRIEF DESCRIPTION OF THE DRAWINGS

FIG. 1 is a perspective structural diagram of an embodiment of a nested container of the present application;

FIG. 2 is a perspective structural diagram of an embodiment of a nested container of the present application, with a top plate of a container body not shown;

FIGS. 3-5 are process diagrams of loading a nested container of the present application into a standard container;

FIG. 6 is a perspective structural diagram of an embodiment of a nested container of the present application, with components disposed at a first side heat dissipation long side not shown;

FIG. 7 is a top view of FIG. 2;

FIG. 8 is a perspective structural diagram of an embodiment of a nested container of the present application, with a second side heat dissipation long side shown;

FIG. 9 is a partial exploded structural view of an embodiment of a nested container of the present application;

FIG. 10 is a partial enlarged view of FIG. 9;

FIG. 11 is a partial exploded structural view of an embodiment of a nested container of the present application;

FIG. 12 is a perspective structural diagram of an embodiment of a first support frame of a nested container of the present application;

FIG. 13 is an M-direction view of FIG. 12;

FIG. 14 is a perspective structural diagram of an embodiment of a second support frame of a nested container of the present application;

FIG. 15 is an N-direction view of FIG. 14;

FIG. 16 is a side view of an embodiment of a nested container of the present application; and

FIG. 17 is a side view of an embodiment of a rack of a nested container server apparatus of the present application.

### REFERENCE NUMERALS

1, 1a, 1b, 1c: nested container
11: corner post
12: bottom side beam
13: top side beam
14: corner member
2, 2a, 2b, 2c: standard container
100: container body
110: first side heat dissipation long side
120: second side heat dissipation long side
130: first side short side
140: second side short side
200, 200a, 200b, 200c, 200d: rack
210, 210a, 210b, 210c, 210d, 210e, 210f, 210g: partition plate
230: extension baffle
310, 310a, 310b: power distribution cabinet
330a1, 330a2, 330b, 330c, 330d, 330e, 330f: power distributor
400: apparatus row
500: maintenance passage
600: door leaf
700: closed wall
801: protective wall
802: cable inlet
900: cooling structure
910, 910a, 910b: fan
920: connection frame
930: support frame
931: first support frame
9311: first support fixing portion
9312: first limiting fixing portion
9313: first support portion
9314: first limiting portion
9315: first auxiliary support portion
932: second support frame
9321: second limiting fixing portion
9322: second upper limiting portion
9323: second lower limiting portion
9324: second upper support portion
9325: second lower support portion
9326: second auxiliary support portion
940: sealing frame
S: container power distribution bracket arrangement

### DETAILED DESCRIPTION

Hereinafter, the technical solutions of the present application are described in detail in conjunction with the drawings and specific embodiments so as to further understand the purposes, solutions and effects of the present application, but not to limit the scope of protection of the appended claims of the present application.

A container server apparatus is a solution that integrates a plurality of servers and network apparatus therefor into a single container body. It features a compact design that can accommodate the plurality of servers and the network apparatus, providing high-performance computing and storage capabilities in a limited space. As a result, it helps to save space and reduce energy costs. The container server apparatus is usually pre-installed with an operating system and management software, and can be easily monitored, managed, and maintained. Since the servers and the network apparatus are all within a single container body, maintenance is also more convenient.

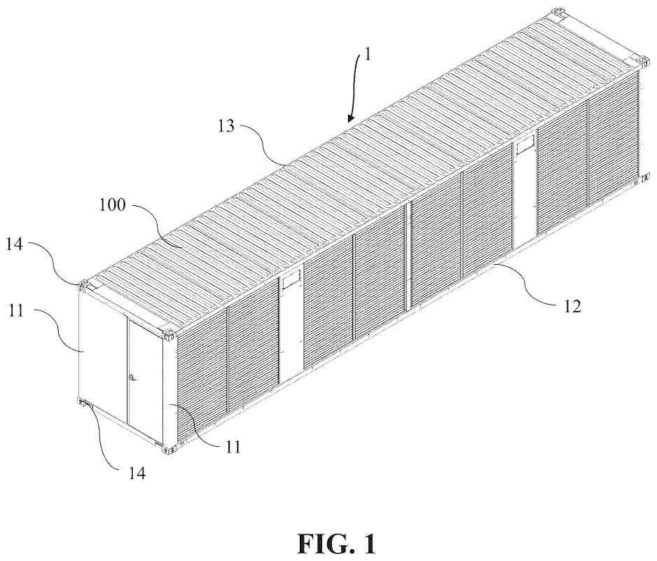

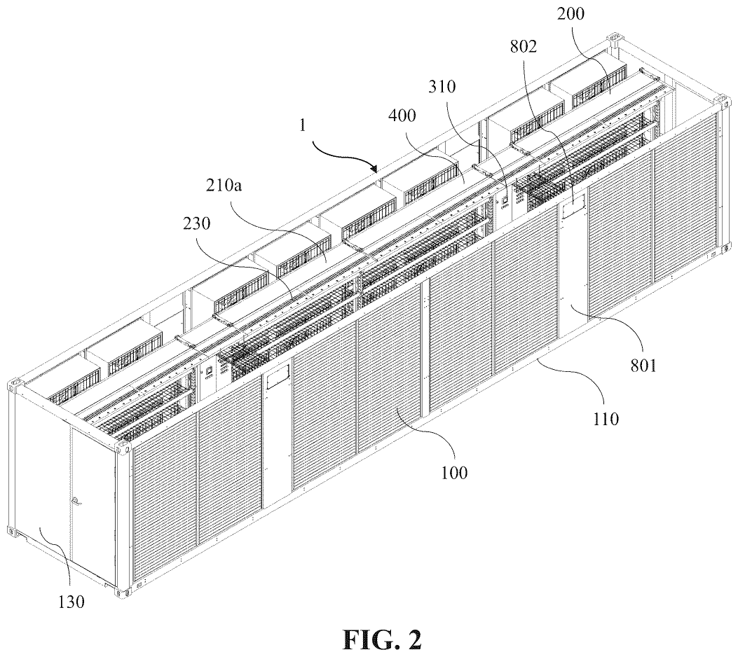

As shown in FIGS. 1 and 2, FIG. 1 and FIG. 2 are an external overall structure illustration view and an internal overall structure illustration view (without a top plate) of an embodiment of a nested container of the present application, respectively. A nested container 1 of some embodiments of the present application includes a container body 100, a rack 200, and an electric control system. The rack 100 and the electric control system are respectively fixed within the container body 100. The electric control system is configured to be connected with a server carried by the rack 200. The electric control system includes a power distribution cabinet 310. The rack 200 and the power distribution cabinet 310 are disposed in a row along a length direction of the container body 100 to form an apparatus row 400.

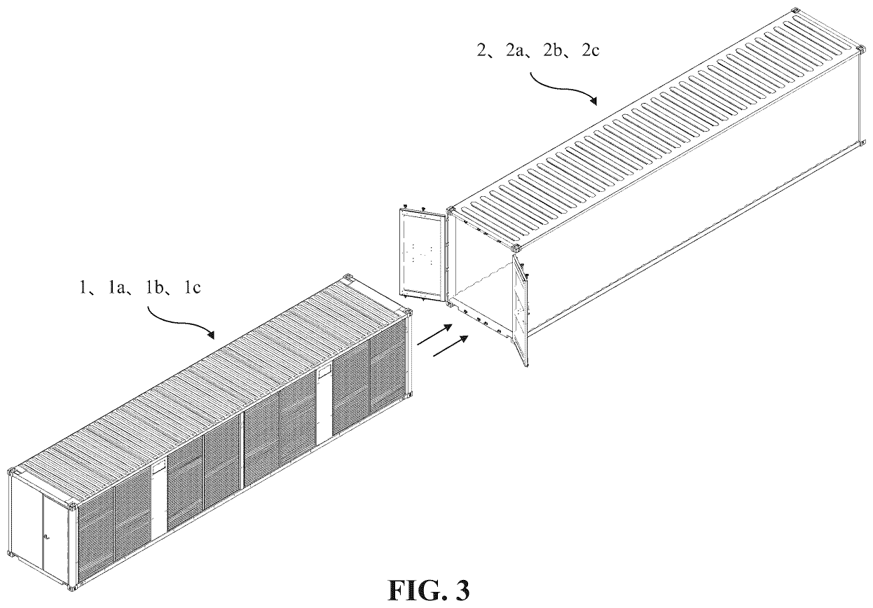

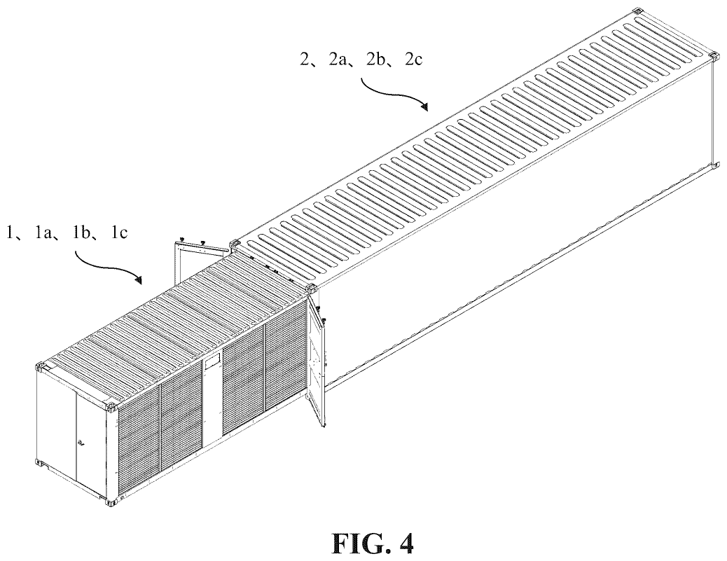

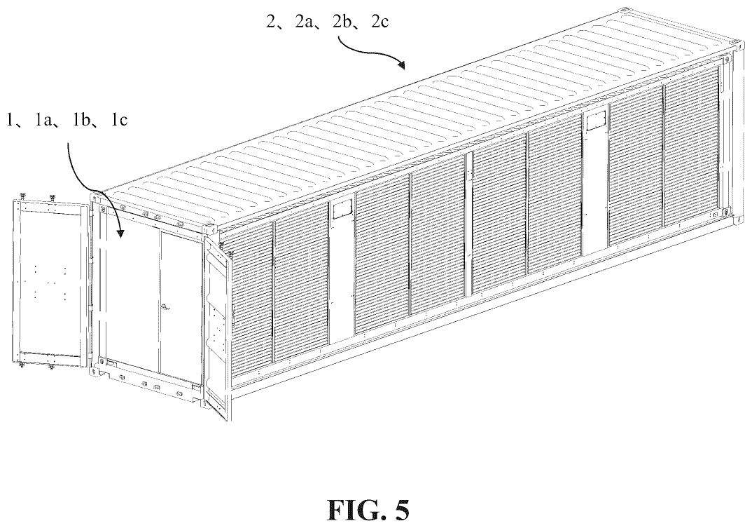

An outer dimension (length, width and height) of the container body 100 of the nested container 1 of some embodiments of the present application is slightly smaller than an inner space dimension of a standard container, so that the nested container 1 of some embodiments of the present application is configured to be entirely loaded into the standard container. With reference to FIGS. 3 to 5, FIGS. 3-5 show loading process diagrams of entirely loading the nested container 1 of some embodiments of the present application into a standard container 2.

As shown in FIG. 1, the nested container 1 of some embodiments of the present application is in a structural form of a standard container. That is, the container body 100 of the nested container 1 of some embodiments of the present application is made of materials such as steel or aluminum alloy, and has the characteristics of high strength, corrosion resistance, and wear resistance. The container body 100 is similar to the standard container and is configured with a corner post 11, a bottom side beam 12, a top side beam 13, a corner member 14, etc. These are main structural components of the container and are configured to support and reinforce the container body 100 to make it strong and rigid enough to withstand the weight of goods and the vibrations and impacts experienced during transportation.

The nested container 1 of some embodiments of the present application combines design compactness, high operational efficiency, high maintenance performance, high structural strength, and high resistance to vibration and impact. Meanwhile, by designing the outer dimension of length, width and height of the container body 100 to be slightly smaller than the inner space dimension of the standard container 2, the nested container 1 of some embodiments of the present application is configured to be entirely loaded into the standard container 2.

The dimension of the standard container is usually specified in accordance with the ISO 668 standard, covering different dimensions such as 20-foot, 40-foot, or 45-foot. Side-opening standard containers, including 20-foot containers (with an approximate length of 6058 mm, width of 2438 mm, and height of 2438 mm), 40-foot (with an approximate length of 12192 mm, width of 2438 mm, and height of 2438 mm), and 40-foot High Cube (with an approximate length of 12192 mm, width of 2438 mm, and height of 2896 mm) are mainstream forms widely used in the logistics and transportation field and have a variety of well-developed loading and unloading measures. Standardized container dimensions make it convenient to load, unload and transport goods, and also improve the efficiency and safety of transportation of the goods.

The nested container 1 of some embodiments of the present application is preferably used in conjunction with 20-foot and 40-foot side-opening standard containers 2. For example, when used in conjunction with a 20-foot standard container 2a, an inner space dimension of the 20-foot standard container 2a being about 5898 mm (length)×2352 mm (width)×2393 mm (height), a nested container 1a has a container body 100 with an outer dimension of length, width, and height slightly smaller than the inner space dimension of the 20-foot standard container 2a.

When used in conjunction with a 40-foot standard container 2b, an inner space dimension of the 40-foot standard container 2b being about 12032 mm (length)×2352 mm (width)×2393 mm (height), a nested container 1b has a container body 100 with an outer dimension of length, width, and height slightly smaller than the inner space dimension of the 40-foot standard container 2b.

When used in conjunction with a 40-foot High Cube standard container 2c, an inner space dimension of the 40-foot High Cube standard container 2c being about 12032 mm (length)×2352 mm (width)×2698 mm (height), a nested container 1c has a container body 100 with an outer dimension of length, width, and height slightly smaller than the dimension of the interior space of the 40-foot High Cube standard container 2c. In terms of practical applications, the 40-foot High Cube, due to its greater height, can carry a higher nested container 1 and has higher integration performance.

It should be noted that the above are merely examples. The nested containers of some embodiments of the present application can be used in conjunction with standard containers of any dimension, all of which fall within the scope of protection of the present application.

In addition, a plurality of nested containers 1 of some embodiments of the present application can be loaded within one standard container. For example, when used in conjunction with the 40-foot standard container 2b, two of the above nested containers la intended to be loaded within the 20-foot standard containers 2a can be loaded within one 40-foot standard container 2b by sequentially loading the two nested containers 1a into the 40-foot standard container 2b along a length direction of the 40-foot standard container 2b.

Alternatively, two nested containers slightly smaller in dimension than a 10-foot standard container and one nested container slightly smaller in dimension than a 20-inch standard container are loaded within the 40-foot standard container 2b by sequentially loading the two nested containers slightly smaller in dimension than the 10-foot standard container and the one nested container slightly smaller in dimension than the 20-inch standard container into the 40-foot standard container 2c along a length direction of the 40-foot standard container 2c. Alternatively, four nested containers slightly smaller in dimension than the 10-foot standard container are loaded within the 40-foot standard container 2b by sequentially loading the four nested containers slightly smaller in dimension than the 10-foot standard container into the 40-foot standard container 2b along the length direction of the 40-foot standard container 2b. Similarly, the 40-foot High Cube standard container 2c can also be loaded with a plurality of nested containers of the same dimension or different dimensions.

The length of the dimension of the interior space inside the container is a distance measured between a box door inner side plate and an end wall inner lining plate, the width is a distance between two inner lining plates, and the height is a distance from a top face of a bottom plate to a bottom face of a top plate. The dimension may vary slightly due to differences among shipping companies.

The server container is in a structural form of a container. The structural design of the container endows it with characteristics such as standardization, generalization, and high efficiency, which facilitates transportation, loading and unloading of goods. However, if the goods are directly containerized for transportation, loading and unloading, varying degrees of damage may be caused to the goods and the container itself in a case where the container is collided or shaken in a process of transporting the container for a long distance, including land and sea transportation. Specific consequences include: damage to the container itself. Due to collision, shaking and other reasons, the container body, door, sealing means and other components of the container may suffer damage, such as deformation, breakage, loose sealing, etc. It is also very possible to endanger the goods in the container. Due to collision, shaking and other reasons, the goods in the container may suffer damage, such as breakage and deformation.

Specific to the nested container 1 of some embodiments of the present application, if the nested container 1 is directly transported as the standard container for a long distance, for example, in sea or land transportation, the nested container 1 is very susceptible to damage during the transportation. In milder cases, the exterior of the container body 100 may suffer damage, including deformation, breakage, etc., and damage caused to an air-cooling structure, an accessory connection structure or the like on the periphery of the container body 100 will directly affect structures of the servers for heat dissipation, sealing and the like, causing the servers and network apparatus to fail to work normally for a long time. In more severe cases, the rack 200, the electric control system or the like within the container body 100 may be damaged, causing the entire system unusable, and resulting in huge losses.

As can be seen, the nested container 2 of some embodiments of the present application has the characteristics of design compactness, high operational efficiency, easy maintenance, safety and reliability. A method for transporting a nested container of some embodiments of the present application includes the following steps:

As shown in FIGS. 3 to 5, a method for transporting a nested container 1 of some embodiments of the present application includes:
placing a nested container 1 configured to dispose a plurality of servers into a standard container 2, wherein an outer contour dimension of the nested container, or its outer dimension of length, width and height, is slightly smaller than an inner space dimension of the standard container; and
unloading the nested container 1 from the standard container.

First to fourth gaps are respectively present between four side walls of a container body 100 of the nested container 1 and four inner walls of the standard container 2, and a fifth gap is present between a top wall of the container body 100 of the nested container 1 and a top inner wall of the standard container 2. Particularly, the first gap and/or second gap are respectively present between left and right side walls of the container body 100 along a length direction and left and right inner walls of the standard container 2 along the length direction. The third gap and/or fourth gap are respectively present between front and rear side walls of the container body 100 along a width direction and front and rear inner walls of the standard container 2 along the width direction. The fifth gap is present between the top wall of the container body 100 and the top inner wall of the standard container 2. A sum of the first gap and the second gap is set to 90±20 mm, a sum of the third gap and the fourth gap is set to 90±20 mm, and the fifth gap is set to 40±10 mm.

The gaps may be distances between four wall faces and a top wall face of the container body 100 and four sides and the top inner wall of the standard container 2. In some embodiments, each corner member 14 of the container body 100 protrudes relative to a wall face, and each gap may also be a distance between a side contour face or a top contour face of each corner member 14 of the container body 100 and four sides and top inner wall of the standard container 2.

The first gap to the fifth gap are configured to provide a relative moving distance when the nested container 1 is loaded into the standard container 2, and to provide assembly tolerance for manufacturing errors, movement shaking, and minor deformations, so as to prevent the nested container 1 from failing to enter the standard container 2, or from being stuck and failing move relatively in a loading process.

When being loaded, the nested container 1 is pushed into the standard container 2 by a forklift or a hydraulic push rod; and when being unloaded, the nested container 1 is pulled out of the standard container 2 by connecting the corner member 14 of the container body 100 of the nested container 1 via a connecting member (e.g., a rope, a steel wire, etc.).

Preferably, the nested container 1 is assisted in pushing in or pulling out of the standard container 2 by mounting rolling or sliding members at the bottom, reducing friction between the nested container 1 and the standard container 2 in loading and unloading processes, thereby reducing vibration and wear. A movement assisting accessory is, for example, a roller connected to the bottom of the container body 100 of the nested container 1, or a slide rail means connected between the bottom of the container body 100 and a bottom plate of the standard container 2.

Particularly, the movement assisting accessory includes a roller means connected to the bottom of the container body 100. The roller means is connected to a bottom of the corner member 14 of the container body 100, or the roller means is connected to the bottom side beam 12 and/or the bottom of the corner member 14 of the container body 100. The roller means is, for example, a metal wheel mounted at the bottom of the container, enabling the container to move on the ground. The container wheel may be fixed or rotatable, so as to facilitate adjustment to a direction of the container.

The movement assisting accessory includes a slide rail means connected to the bottom of the container body 100 or to a bottom plate of the standard container 2.

The movement assisting accessory includes a slide plate means connected to the bottom of the container body 100 or to the bottom plate of the standard container 2. The slide plate is mounted between the bottom of the standard container and the bottom of the nested container. The slide plate means is made of, for example, a metal sheet, allowing relative sliding to generate between the nested container and the standard container, thereby reducing friction when the container moves.

The nested container further includes a tensioning member connected between the corner member 14 of the container body 100 and the inner wall of the standard container 2. Particularly, after the nested container 1 is pushed into the standard container 2, the corner member 14 of the container body 100 of the nested container 1 is connected with a rope ring disposed at a respective corner in the standard container 2 via the tensioning member. The tensioning member is, for example, a bolt tensioner, which uses a bolt and a nut to achieve the purpose of tensioning by tightening; the structure is stable, and it is convenient to assembly and disassembly. The tensioning member may also be a tensioning rod, which uses a pull rod or a connecting rod to firmly connect the two components, with a nut for tightening in the middle; the structure is lightweight. Alternatively, the tensioning member is a steel wire member, which has very large pulling force and good flexibility; it is easy to operate.

After the nested container 1 is pushed into the standard container 2, a buffer member is placed in at least one of the first gap to the fifth gap, which can further prevent shaking and collision.

The buffer member includes a wooden structural member, a corner protection structural member, a ridge structural member, a foam member, etc. The wooden structural member is disposed at a bottom of at least one of the first gap to the fifth gap. The corner protection structural member is mounted on the corner member 14 of the container body 100. The corner protection structural member is, for example, a wooden material member, a plastic material member, a foam material member or a rubber material member. The corner protection structural member buffers the corner member 14 part of the container body 100, to reduce a force created when the corner member 14 collides with an interior of the standard container 2, and protects the container body 100 from damage. The ridge structural member is mounted to at least one of a corner post 11, a bottom side beam 12, and a top side beam 13 of the container body 100. The ridge structural member is, for example, in an L-shape, and is a wooden material member, a plastic material member, a foam material member or a rubber material member. The ridge structural member buffers the side beam and corner post parts of the container body 100, reducing a force generated when the side beams and the corner post collide with the inside of the standard container 2, thereby ensuring safety of the container body. The foam member is filled in at least one of the first gap to the fifth gap. The foam member is used for forming buffer between wall faces of the container body 100 and the standard container 2.

The above buffer members may be used in combination to respectively provide buffering protection or multiple protection to different parts of the container body 100.

In some embodiments of the present application, the nested container 1 further includes a limiting member disposed in at least one of the first gap to the fifth gap for limiting a position of the nested container 1 in the standard container 2 and reducing a possibility of collision between the nested container 1 and the standard container 2.

The limiting member includes left and right side limiting structural members disposed in the first gap and/or the second gap and disposed along the length direction of the standard container 2 so as to define the third and fourth gaps to remain equal when the nested container is loaded within the standard container. For example, the left and right side limiting structural members with a certain width (e.g., 35 mm) are mounted on left and right sides of an entrance of the standard container 2, so that the nested container 1 can be located in the middle of the width direction of the standard container 2 when loaded. When the nested container 1 is entirely loaded into the standard container 2, the first gap and the second gap formed at the front and rear sides of the nested container 1 from the standard container 2 along the length direction are substantially equal. The left and right side limiting structural members may be disposed at any position between the standard container 2 and the nested container 1 in a height direction in the first gap and the second gap.

The limiting member includes front and rear side limiting structural members disposed in the third gap and/or the fourth gap away from the entrance of the standard container 2 so as to define the third and fourth gaps to remain equal when the nested container 1 is loaded within the standard container 2. For example, when the nested container 1 is loaded within the standard container 2, the third gap is formed between an end of the entrance of the standard container 2 and the nested container 1, and the fourth gap is formed between the other end away from the entrance end and the nested container 1. The front and rear side limiting structural members with a certain width (e.g., 30 mm) may be disposed in the fourth gap, so that when the nested container 1 is loaded within the standard container 2, once a front end of the nested container 1 abuts against the front and rear side limiting structural members, this indicates that the nested container 1 has been loaded in place, and the third gap and the fourth gap on the front and rear sides of the nested container 1 and the standard container 2 can be kept relatively equal. When the nested container 1 is loaded in place, the front and rear side limiting structural members with a certain width are likewise disposed in the third gap at the entrance, avoiding the nested container 1 from shifting in the standard container 2 in front and rear directions. The front and rear side limiting structural members may be disposed at any position between the standard container 2 and the nested container 1 in the height direction in the third gap and the fourth gap.

In some embodiments of the present application, as shown in FIGS. 2, 6, and 7, the rack 200 and the power distribution cabinet 310 are disposed in a row along the length direction of the container body 100 to form an apparatus row 400, making full use of a space inside the container body 100. Preferably, in some embodiments of the present application, the racks 200 are configured to be symmetrically disposed on both sides of the power distribution cabinet 310.

By providing a symmetrical configuration of the racks 200 on the two sides of the power distribution cabinet 310, the same number of servers of the same specifications can be arranged on the racks 200, so that power lines leading out of the power distribution cabinet 310 to two ends are evenly distributed and clearly routed, which makes it easy for the staff to manage and maintain.

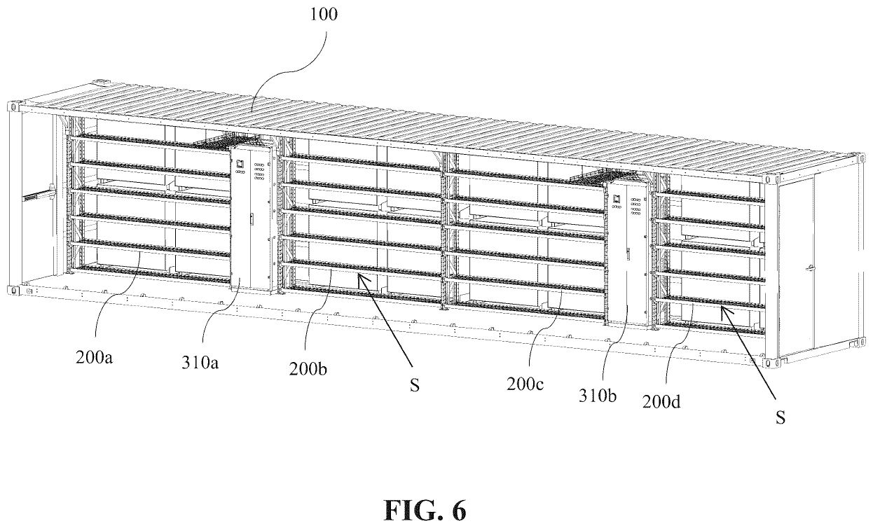

In this embodiment, as shown in FIG. 6, one rack 200a and one rack 200b are respectively configured on the two sides of the power distribution cabinet 310a. The racks 200a and 200b have the same specifications, or in other words, the racks 200a and 200b have the same length, width, and height so as to have the ability to carry the same number of servers of the same specifications.

It should be noted that the “one” rack here does not refer to one in the physical sense, but means that the racks on the two sides of the power distribution cabinet have the same specifications and the same ability to carry servers, so that the power distribution cabinet evenly supplies power to the two sides. The racks on the two sides of the power distribution cabinet may also be connected to each other to form an integrated whole.

In other embodiments, the two sides of the power distribution cabinet 310 may be symmetrically configured with two or more racks 200 of the same number and specifications, so as to ensure that the power distribution cabinet 310 evenly routes lines and transmits power to servers on the racks in directions of the two sides. For example, two sides of a power distribution cabinet 310a are respectively configured with the racks 200a and 200b of the same specifications, and two sides of a power distribution cabinet 310b are respectively configured with racks 200c and 200d of the same specifications. Preferably, the racks 200a, 200b, 200c, and 200d have the same specifications, so that balance can be achieved in both power line distribution and weight distribution.

Still further, the power distribution cabinet 310 and the racks 200 on the two sides thereof serve as a container power distribution bracket arrangement S. In some embodiments, according to the dimension of the container body 100, computing power requirements, and power distribution manners, a plurality of container power distribution bracket arrangement S may be provided and arranged side by side in a row. On the premise of ensuring the reliability of electrical control measures such as power distribution, the number of configurable servers is multiplied, and the computing power of the nested container server apparatus is multiplied. When the computing power of the nested container server apparatus is increased, requests and tasks can be processed faster, thereby improving response speed and processing efficiency, supporting the processing of large amounts of data and more complex applications, and meeting higher performance requirements.

The above electric control system not only has power distribution function, but also includes air conditioning function, cabinet power management function, remote monitoring function and the like, which ensure the normal operation and management of the server container through collaboration among various components. The air conditioning function part includes an air conditioning controller, a compressor, a fan and other components, which are used for maintaining a temperature and humidity inside the server container; the cabinet power management function part is used for monitoring and managing a power supply of each cabinet, including powering on and off, restarting, monitoring power consumption, etc.; the remote monitoring function part is used for remotely monitoring a status of the server container, including collecting and analyzing information such as temperature, humidity, power consumption, and network connection.

With reference to FIGS. 2, 6, and 7, the container body 100 of the nested container 1 of some embodiments of the present application includes a first side heat dissipation long side 110, a second side heat dissipation long side 120, a first side short side 130, and a second side short side 140, wherein the first side heat dissipation long side 110 and the second side heat dissipation long side 120 are symmetrically disposed along the length direction of the container body 100, and the first side short side 130 and the second side short side 140 are symmetrically disposed along the width direction of the container body 100.

In some embodiments of the present application, a side wall of the container body 100 corresponding to the first side heat dissipation long side 110 and a side wall of the container body 100 corresponding to the second side heat dissipation long side 120 are provided with an air inlet and an air outlet, and a heat dissipation channel is formed between the air inlet and the air outlet. In some embodiments of the present application, the side wall of the container body 100 corresponding to the first side heat dissipation long side 110 and/or the side wall of the container body 100 corresponding to the second side heat dissipation long side 120 are provided with a cooling structure 900. In some embodiments of the present application, the side wall of the container body 100 corresponding to the first side heat dissipation long side 110 and/or the side wall of the container body 100 corresponding to the second side heat dissipation long side 120 are provided with a dustproof mesh and/or a louver. In some embodiments of the present application, the side wall of the container body 100 corresponding to the first side heat dissipation long side 110 is provided with a water curtain cooling structure, and the side wall of the container body 100 corresponding to the second side heat dissipation long side 120 are provided with a fan cooling structure.

The apparatus row 400 formed by disposing the rack 200 and the power distribution cabinet 310 in a row is disposed along a direction in which the first side heat dissipation long side 110 and the second side heat dissipation long side 120 extend, and two sides of the apparatus row 400 respectively abut against the first side short side 130 and the second side short side 140.

The nested container server apparatus is a high-power density device that consumes a great amount of electrical energy to work, and accordingly generates a great amount of heat in a working process, which requires heat dissipation treatment to ensure the normal operation of the apparatus. The nested container 1 of some embodiments of the present application employs air cooling for heat dissipation, which is a high-efficiency and low-consumption heat dissipation manner involving a principle of introducing external air into the inside of the container, transferring heat to the air, and then discharging the hot air to the outside of the container to reach the purpose of heat dissipation.

As shown in FIGS. 1, 7, and 8, the first side heat dissipation long side 110 is provided with an air inlet structure, and the second side heat dissipation long side 120 is provided with a cooling structure 900. The first side heat dissipation long side 110 and the second side heat dissipation long side 120 oppositely disposed form an air flow to dissipate heat from and cool the servers in the container body 100. Some embodiments of the present application achieve a simple structure, low costs, and good heat dissipation effect by oppositely disposing the first side heat dissipation long side 110 and the second side heat dissipation long side 120.

In an embodiment, a louver structure is provided on the first side heat dissipation long side 110, and the cooling structure 900 is provided on the second side heat dissipation long side 120; alternatively, a dustproof mesh structure is provided on the first side heat dissipation long side 110, and the cooling structure 900 is provided on the second side heat dissipation long side 120, wherein the dustproof mesh structure is, for example, a metal cut mesh or a metal woven mesh with mesh holes; alternatively, louver and dustproof mesh structures are provided on the first side heat dissipation long side 110, and the cooling structure 900 is provided on the second side heat dissipation long side 120, both having good impurity prevention and wind cooling effects; alternatively, a water curtain cooling structure is mounted on the outer side of the first side heat dissipation long side 110, so that air outside the container body 100 enters into cavities through a wet curtain with strong water absorption, water on the wet curtain evaporates under an adiabatic state to remove a large amount of latent heat, the purified, cooled and oxygenated cold air is fed into the container body 100, and through continuous convection, the heat dissipation effect is further improved. Alternatively, at least two of the dustproof mesh structure, the louver structure, and the water curtain cooling structure are mounted on the outer and/or inner side(s) of the first side heat dissipation long side 110.

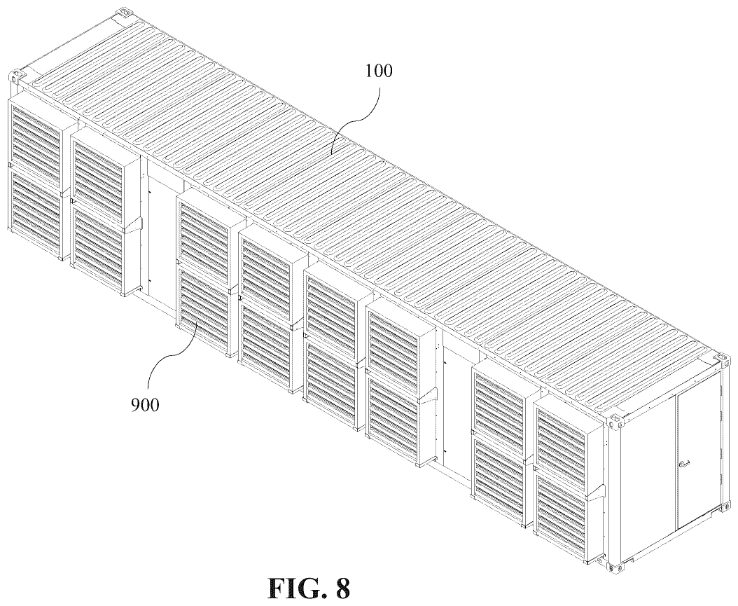

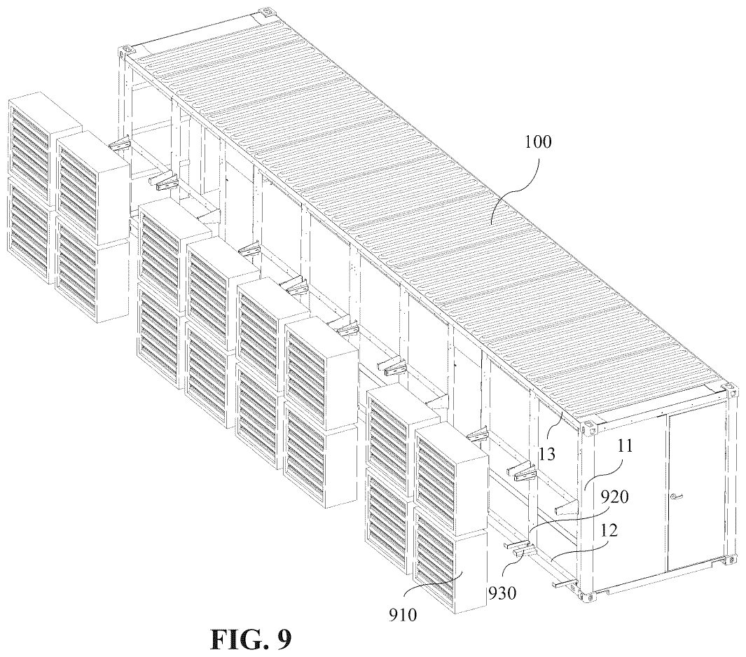

As shown in FIGS. 8 and 9, the cooling structure 900 includes a plurality of fans 910. By introducing external air into the inside of the container and allowing the air to flow through the fans 910, the heat will be removed, so as to keep a temperature inside the container and prevent it from being too high. In other embodiments, the fans 910 may be used in combination with heat dissipation pipes consisting usually of a series of metal pipes, through which heat is transferred to walls of the container and then dissipated to the external air. This manner can increase the heat dissipation area of the container and improve the heat dissipation effect. Alternatively, the fans 910 may be used in combination with heat dissipation fins consisting usually of a series of metal fins, through which heat is transferred to the air and then removed. This manner can increase the heat dissipation area of the container and improve the heat dissipation effect. In order to ensure the heat dissipation effect, it is necessary to ensure smooth air circulation around the container.

The cooling structure 900 further includes a connection frame 920 and a support frame 930. The connection frame 920 is connected to the bottom side beam 12 and the top side beam 13 of the container body 100. Alternatively, in some embodiments, the connection frame 920 is connected to the bottom side beam 12, the top side beam 13 and the corner post 11 of the container body 100, making the structure stable.

The support frame 930 is detachably connected to the connection frame 920 via a plurality of fasteners. The fans 910 are disposed on the support frame 930. Furthermore, the fans 910 are connected with the power distribution cabinet 310 of the electric control system.

Particularly, the cooling structure 900 is connected between the bottom side beam 12, the top side beam 13 and the corner post 11 of the second side heat dissipation long side 120 of the container body 100. When the nested container 1 of some embodiments of the present application is transported for a long distance, the support frame 930 is connected to an inner side of the connection frame 920 located inside the container body 100, and the fans 910 are located on the support frame 930. That is to say, the fans 910 are located in a space between the second side heat dissipation long side 120 and the apparatus row 400, and will not protrude outside the container body 100. When the nested container 1 of some embodiments of the present application is in use, the fans 910 may be in a state during transportation, that is, the fans 910 are still working while being built into the container body 100. The support frame 930 is detachably connected to the inner side of the connection frame 920 located inside the container body 100. Meanwhile, an outer side of the connection frame 920 located outside the container body 100 likewise have support frame connecting portions. The support frame 930 may be connected to the support frame connecting portions of the connection frame 920 located on the outer side of the container body 100, achieving outer placement of the fans 910.

In some embodiments of the present application, there are a plurality of groups of connection frames 920, for example, wherein at least one group of connection frames 920 is partially connected to a front corner post of the container body 100 located on the front side, and at least one group of connection frames 920 is partially connected to a rear corner post of the container body 100 located on the rear side. Of course, in some embodiments, there may also be a group of connection frames 920.

In the embodiments shown in FIGS. 6 and 9, there are four groups of connection frames 920 respectively corresponding to servers carried on the rack 200a, servers carried on the rack 200b, servers carried on the rack 200c, and servers carried on the rack 200d, making the heat dissipation performance better. Each group of the connection frames 920 carries four fans via the support frame 930. The four fans arranged in the 2×2 grid pattern, resembling the character ‘ [symbol] ’. However, some embodiments of the present application do not limit the number of the fans in the cooling structure 900, and the fans can be arranged according to their sizes, shapes, and airflow rate, provided that the heat dissipation requirement is met.

The support frame 930 is formed by bending and processing a metal sheet, for example. Specifically, the support frame 930 is processed to form a fixing portion configured to detachably connect to the inner side or outer side of the connection frame 920 via a fastener, a support portion configured to support the fan, and a limiting portion configured to limit the fan 910 on the support portion to avoid the fan 910 from moving or shaking.

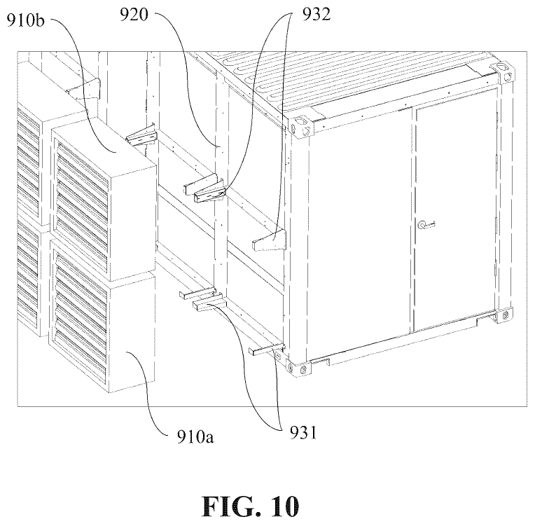

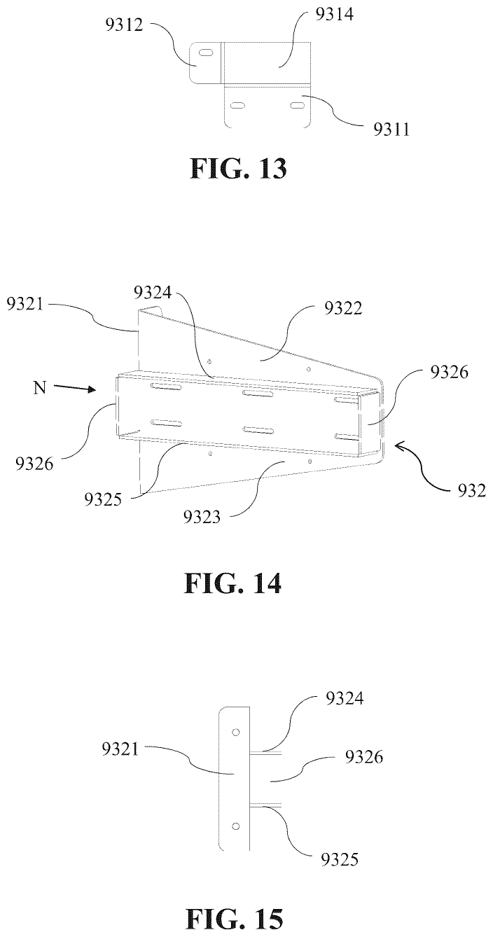

With reference to FIGS. 10, 12, and 13, the support frame 930 includes a first support frame 931. The first support frame 931 includes a first support fixing portion 9311, a first limiting fixing portion 9312, a first support portion 9313, and a first limiting portion 9314. The first support fixing portion 9311 is connected with the first support portion 9313, and the first limiting fixing portion 9312 is connected with the first limiting portion 9314. Taking a horizontal support surface of the first support portion 9313 as a reference, the first support fixing portion 9311 is formed, for example, by bending a metal sheet integral with the first support portion 9313 downward by ninety degrees, the first limiting portion 9314 is formed, for example, by bending the metal sheet integral with the first support portion 9313 upward by ninety degrees, and the first limiting fixing portion 9312 is formed, for example, by bending the metal sheet integral with the first limiting portion 9314 by ninety degrees in a direction away from the first support portion 9313. Preferably, the first support fixing portion 9311 and the first limiting fixing portion 9312 are in the same plane. As shown in FIG. 12, the first support fixing portion 9311 is connected to the side of a short side of the first support portion 9313, and there are two first limiting portions 9314 connected to two adjacent sides (the side of a long side and the side of a short side) of the first support portion 9313 that are different from the side connected to the first support fixing portion 9311, wherein the two first limiting portions 9314 form a limiting angle. The side of the other short side of the first support fixing portion 9311 is further bent downward to form a first auxiliary support portion 9315. The first auxiliary support portion 9315 functions as a stiffener, which can increase the support strength of the first support fixing portion 9311.

The first support fixing portion 9311 and the first limiting fixing portion 9312 are respectively provided with a connection hole. The fasteners are connected with the inner side or the outer side of the connection frame 920 via the connection holes on the first support fixing portion 9311 and the first limiting fixing portion 9312.

With reference to FIG. 10, the first support frame 931 is disposed corresponding to a corner of a fan 910a, and two first support frames 931 are oppositely disposed and correspond respectively to two corners at a bottom of the fan 910a. The other two corners at the bottom of the fan 910a may be supported on the connection frame 920. That is to say, the two corners at the bottom of the fan 910a that are farther from the second side heat dissipation long side 120 are respectively limited by limiting angles of the first support frames 931 constituted by the first limiting portions 9314, and the two corners at the bottom of the fan 910a that are closer to the second side heat dissipation long side 120 are supported by the connection frame 920.

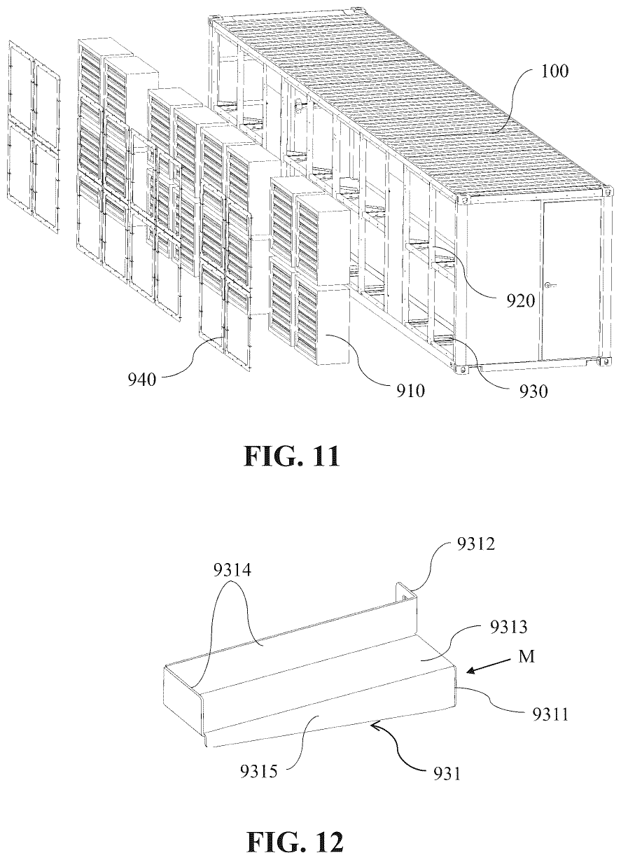

Meanwhile, as shown in FIG. 11, the cooling structure 900 further includes a sealing frame 940. The sealing frame 940 is, for example, an integrally formed metal member. The fan 910 is limited and sealed from the outer side of the container body 100 via the sealing frame 940.

Preferably, four corners of the fan 910 are supported and limited by the first support frame 931. Four first support frames 931 are oppositely connected to the connection frame 920 corresponding to the four corners of the fan 910.

It should be noted that the above connection frame 920 is, for example, in the shape of a square. When the fans 910 are arranged in the 2×2 grid pattern, resembling the character ‘ [symbol] ’, the connection frame 920 is, for example, in the 2×2 grid pattern, resembling the character ‘ [symbol] ’, and the fans 910 are connected in each opening of the connection frame 920.

In some embodiments, the connection frame 920 is, for example, in the shape of long rods. When the fans 910 are arranged in the 2×2 grid pattern, resembling the character ‘ [symbol] ’, the connection frame 920 is, for example, in the shape of a cross, and the cross-shaped connection frame 920, along with the top side beam 13, the bottom side beam 12 and the corner post 11 of the container body 100, constitutes a frame for the first support frames 931 to connect. For example, the first support frames 931 corresponding to bottom corners of a fan 910 may be connected to the corner post 11 and/or the bottom side beam 12, and the first support frames 931 corresponding to top corners of the fan 910 may be connected to the corner post 11 and/or the top side beam 13. At this point, the other two corners at the bottom of the fan 910 may be supported on the bottom side beam 12.

The sealing frame 940 is disposed along four sides of the fan 910. There is a sealant or a sealing tape between the sealing frame 940 and the connection frame 920.

As shown in FIGS. 10, 14, and 15, the support frame 930 further includes a second support frame 932 connected between fans 910a and 910b disposed above and below for supporting and limiting upper corners of the lower fan 910a and bottom corners of the upper fan 910b. That is, the second support frame 932 can complete the functions of two first support frames 931 disposed adjacent to each other above and below. When the fans 910 are disposed above and below, the second support frame 932 may be employed to replace two first support frames 931 disposed adjacent to each other above and below, which can reduce an area occupied by the support frames, increase an area for the fans, and thereby improve the airflow rate.

As shown, the second support frame 932 includes a second limiting fixing portion 9321, a second upper limiting portion 9322, a second lower limiting portion 9323, a second upper support portion 9324, and a second lower support portion 9325. The second upper limiting portion 9322 and the second lower limiting portion 9323 are disposed above and below, the second limiting fixing portion 9321 is connected to vertical side edges of the second upper limiting portion 9322 and the second lower limiting portion 9323, and the second upper support portion 9324 and the second lower support portion 9325 are transversely connected between the second upper limiting portion 9322 and the second lower limiting portion 9323.

The second upper limiting portion 9322 and the second lower limiting portion 9323 are formed as an integral vertically disposed metal sheet. Taking limiting faces of the second upper limiting portion 9322 and the second lower limiting portion 9323 facing the fans 910 as a reference, the second limiting fixing portion 9321 is formed, for example, by bending a metal sheet integral with the second upper limiting portion 9322 and the second lower limiting portion 9323 in a direction away from the fans 910. The second upper support portion 9324 and the second lower support portion 9325 are connected to surfaces where the limiting faces of the second upper limiting portion 9322 and the second lower limiting portion 9323 are located, and are disposed above and below. The second upper support portion 9324 is formed, for example, by bending an upper side edge of the vertically disposed metal sheet connected between the second upper limiting portion 9322 and the second lower limiting portion 9323 downward by ninety degrees toward a direction where the fans 910 are located, and the second lower support portion 9325 is formed, for example, by bending a lower side edge of the vertically disposed metal sheet connected between the second upper limiting portion 9322 and the second lower limiting portion 9323 upward by ninety degrees toward the direction where the fans 910 are located.

Further, the second support frame 932 further includes a second auxiliary support portion 9326, which is connected between the second upper support portion 9324 and the second lower support portion 9325 disposed in parallel above and below. There are two second auxiliary support portions 9326 oppositely disposed, which, for example, are formed by bending left and right side edges of the vertically disposed metal sheet where the second upper support portion 9324 and the second lower support portion 9325 are located by ninety degrees toward the second upper support portion 9324 and the second lower support portion 9325. The second auxiliary support portions 9326 function to provide reinforcement support and can enhance the supporting strength of the second upper support portion 9324 and the second lower support portion 9325.

The second limiting fixing portion 9321 is provided with a connection hole. A fastener is connected with the inner side or the outer side of the connection frame 920 via the connecting hole in the second limiting fixing portion 9321.

In some embodiments of the present application, when there are a plurality of fans 910 arranged and disposed above and below, the first support frame 931 may correspond to bottom corners of a lower fan 910, or the first support frame 931 may correspond to the bottom corners of the lower fan 910 and top corners of an upper fan 910, and the upper and lower fans 910 are supported and limited by the second support frame 932. The second upper limiting portion 9322 and the second upper support portion 9324 of the second support frame 932 respectively correspond to bottom corners of the upper fan 910, and the second lower limiting portion 9323 and the second lower support portion 9325 of the second support frame 932 respectively correspond to top corners of the lower fan 910.

When the fans 910 are disposed in three or even more layers, the first support frame 931 and the second support frame 932 are used in the same manner as above. The first support frame 931 is disposed corresponding to bottom corners of a fan on a bottom layer and top corners of a fan on a top layer, and the second support frame 932 is disposed corresponding to the other opposite corners of the fans except the bottom corners and the top corners for simultaneously supporting and limiting the corresponding corners of the two upper and lower fans.

It should be noted that only the first support frame 931 may be employed in a case where a side face space of the container body 100 allows, or the airflow rate of the fans 910 is sufficient for use. Of course, in some embodiments, only the second support frame 932 may be employed.

The first support portion 9313 of the first support frame 931 and the support surface of the connection frame 920 that supports the fan 910 are substantially in the same plane. When the fan 910 needs to be placed outside, the sealing frame 940 on the outer side of the container body 100 is removed, the first support frame 931 and/or the second support frame 932 are connected to the connection frame 920 on the outer side of the container body 100, and the fan 910 may be pulled to the outer side of the container body 100 along a plane constituted by the first support portion 9313 of the first support frame 931, the second upper support portion 9324 and second lower support portion 9325 of the second support frame 932, and the connection frame 920. In a pulling process, the first limiting portion 9314 of the first support frame 931 and the second upper limiting portion 9322 and second lower limiting portion 9323 of the second support frame 932 constitute a movement limit on the fan 910.

When the nested container 1 of some embodiments of the present application is loaded and transported, the support frame 930 of the cooling structure 900 is connected to the connection frame 920 inside the container body 100 via fasteners. In actual use, the fan 910 may be external or built-in to meet the requirements of different geographical conditions and heat dissipation conditions.

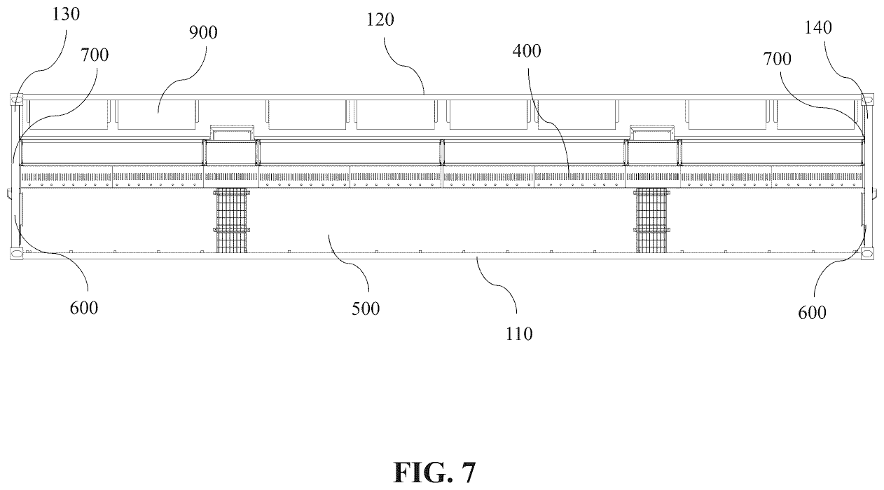

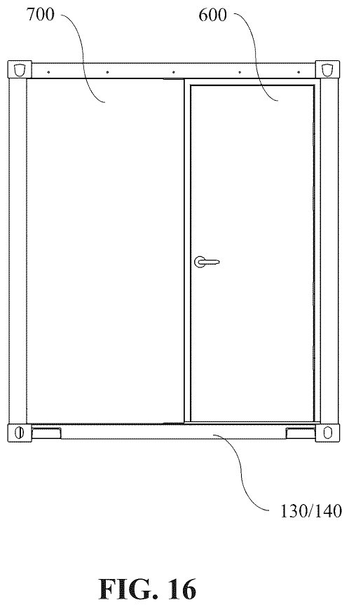

As shown in FIGS. 7 and 16, a maintenance passage 500 is provided between the first side heat dissipation long side 110 and the apparatus row 400, and door leaves 600 are provided at positions of the first side short side 130 and the second side short side 140 corresponding to the maintenance passage 500.

The apparatus row 400 is disposed in parallel between the first side heat dissipation long side 110 and the second side heat dissipation long side 120, and the maintenance passage 500 between the first side heat dissipation long side 110 and the apparatus row 400 is used for the staff to conduct regular inspection, maintenance and upkeep for systems, apparatus, networks, and the like to ensure that they can normally operate, prevent failures and accidents, and improve the reliability and stability of the systems. The regular maintenance and upkeep can extend the service life of the systems, apparatus, networks, and the like, reduce the frequency and cost of replacement and repair, and optimize the system performance by optimizing and adjusting the systems, apparatus, networks, and the like, thereby improving system performance and efficiency and reducing resource wastes. Meanwhile, the maintenance passage can also be used to perform security inspection and protection on the systems, apparatus, networks, and the like to ensure the security and confidentiality of information. As can be seen, the maintenance passage plays an important role in ensuring the normal operation of the systems and improving the reliability, stability, performance and security of the systems.

The maintenance passage 500 of some embodiments of the present application is spacious and smooth, and at least one of the first side short side 130 and the second side short side 140 corresponding to the maintenance passage 500 is provided with a door leaf 600. In this embodiment, door leaves 600 are respectively disposed on the first side short side 130 and the second side short side 140, and the staff may enter the maintenance passage 500 from one of the door leaves 600, inspect, maintain and service the systems, apparatus and networks in the container body 100, and then walk out from the other door leaf 600, which is convenient and quick and can effectively improve the operational efficiency.

In an embodiment of the nested container 1 of some embodiments of the present application, positions of the first side short side 130 and the second side short side 140 corresponding to the rack 200 and between the rack 200 and the second side heat dissipation long side 120 are provided with closed walls 700. That is to say, the door leaves 600 disposed on the first side short side 130 and the second side short side 140 are half-open door leaves, and only the positions thereof corresponding to the maintenance passage 500 are provided with openable/closable door leaves, while the positions of the first side short side 130 and the second side short side 140 not corresponding to the maintenance passage 500 are full-height closed walls, which simplifies unnecessary design, and reduces safety hazards and the costs of maintenance and apparatus manufacturing.

Meanwhile, a door lock is disposed on the door leaf 600, which supports a plurality of door opening manners, such as password, fingerprint, card swiping, etc. A suitable unlocking manner may be selected according to an actual case. The door lock also supports a plurality of alarm manners, such as sound alarm or SMS alarm, and alarms are issued for cases where unlocking settings are not met, so as to avoid losses.

In addition, permission management of the door lock may be performed by setting an administrator password to ensure that only the authorized know the password. Further, the door lock permissions are set for different users, such as administrators, maintenance personnel, ordinary users, and the like. Different users have different permissions, which can achieve better management of the door lock. For example, parameters of the door lock such as door opening time, door closing time, and alarm time may be set, so as to meet different usage needs. For example, the door opening time for the ordinary users is limited to a shorter time, the door opening time for the maintenance personnel is a longer time, and the door opening time for the administrators is unlimited, etc.

In the nested container 1 of some embodiments of the present application, as shown in FIGS. 1, 2, and 7, the apparatus row 400 consisting of the power distribution cabinet 310 and the rack 200 is located between the first side heat dissipation long side 110 and the second side heat dissipation long side 120. The first side heat dissipation long side 110 is provided with a louver (and/or a dustproof mesh). Part of the first side heat dissipation long side 110 corresponding to the power distribution cabinet 310 of the apparatus row 400 is further provided with a protective wall 801, and the louver (and/or the dustproof mesh) are disposed corresponding to the position of the rack 200, ensuring that external wind enters the container body 100 through the louver (and/or the dustproof mesh), while avoiding moisture or sunlight from damaging the power distribution cabinet 310. As shown in FIG. 9, the protective wall 801 is disposed between adjacent louvers (and/or the dustproof meshes).

The protective wall 801 is made of, for example, a steel plate and the corner post. Parts of the protective wall 801 may be reinforced with transverse and longitudinal stiffeners to increase the overall strength of the container body 100, enhance the resistance of the container body 100 to deformation and extrusion, and reduce the likelihood of damage during loading, unloading and transportation.

Further, the top of the protective wall 801 has a cable inlet 802 disposed corresponding to a top end of the power distribution cabinet 310.

Server power cables need to use of high-quality copper-core cables, so as to ensure the stability and reliability of current transmission. Meanwhile, sheaths of the cables should have certain properties, such as wear resistance, high temperature resistance, and corrosion resistance. The length of the server power cables needs to be selected according to actual cases. In general, the cable length should not be too long, so as to avoid excessive resistance and power loss in a current transmission process. The server power cables need to have certain safety properties, such as fireproof, explosion-proof, and electric shock-proof properties. When selecting cables, attention should be paid to whether they comply with relevant safety certification standards, such as UL, CE, and the like.

A server consumes a lot of electricity, and the cross-sectional area of the server power cables needs to be large enough to meet the high-power requirement of the server. When the power distribution cabinet 310 needs to power a large number of servers, both the number and volume of power cables connected with the power distribution cabinet 310 are relatively large.

In some embodiments of the present application, by disposing at a top end of the protective wall 801 the cable inlet 802 that directly corresponds to the top of the power distribution cabinet 310, the power cables are introduced through the cable inlet 802 and connected to the power distribution cabinet 310, resulting in a direct path. This shortens a length of the power cables inside and outside the container body 100, reduce a space occupied by the power cables in the container body 100, avoid accumulation and extension of a large number of large-volume power cables in the container body 100, and facilitate the staff's daily inspection, maintenance and upkeep work on the systems, apparatus and networks in the container body 100.

Further, a water curtain cooling structure is mounted on the outer side of the first side heat dissipation long side 110, so that air outside the container body 100 enters into cavities through a wet curtain with strong water absorption, water on the wet curtain evaporates under an adiabatic state to remove a large amount of latent heat, the purified, cooled and oxygenated cold air is delivered into the container body 100, and through continuous convection, the heat dissipation effect is further improved.

During transportation, the water curtain cooling structure is stored in the container body 100 by means of a water curtain storage structure. For example, the water curtain storage structure for fixing the water curtain is disposed on an inner side of the protective wall 801. The water curtain storage structure may be a hook, a rope ring, a clamping groove, and the like. When in use, the water curtain cooling structure is taken out from the container body 100 and mounted on an outer side of the dustproof mesh and/or the louver along the first side heat dissipation long side 110.

The nested container 1 of some embodiments of the present application further includes an accessory box fixed inside the container body 100 for loading necessary accessory facilities such as awnings, awning fixings, water curtain pipelines, communication pipelines, and the like.

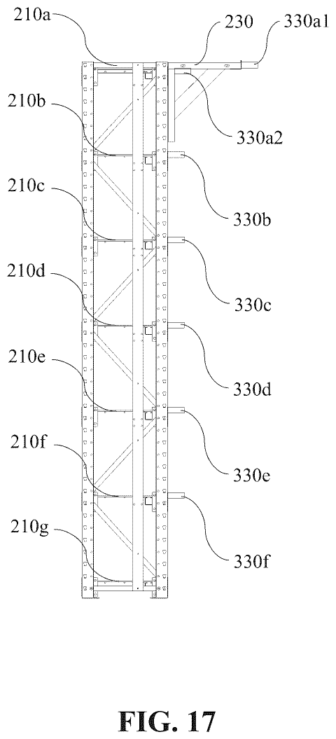

As shown in FIGS. 2 and 17, the rack 200 in the nested container 1 has a plurality of partition layers for placing servers. A distance between the partition layers corresponds to a height of an upright server. That is, the servers are arranged upright on the partition layers of the rack 200. At the top of the rack 200, the space above it up to the top of the container body 100 is not enough to accommodate an upright server apparatus. In order to improve the computing power of the nested container server apparatus, increasing the number of servers is an effective way to achieve enhanced computing power while ensuring the computing power of a single server.

In some embodiments of the present application, an extension baffle 230 is provided to extend a length of a partition plate 210 at an uppermost layer of the rack 200 along the width direction of the container body 100, so that a server can be laid flat thereon, which increases the number of integrated servers and can improve the computing power of the nested container server apparatus. Of course, in a case where the top space allows, a server located at the topmost layer may be normally arranged upright.

The electric control system includes a plurality of power distributors. There are two power distributors on the partition plate at the topmost layer of the rack 200, one of which is connected with the server on the partition plate at the topmost layer of the rack 200, and the other of which is connected with a server on a partition plate at a layer directly below the same. The servers on the remaining partition plates are connected with the power distributors on the partition plates at respective upper layers.

Taking the rack 200 shown in FIG. 17 as an example, the rack 200 has seven partition plates 210a to 210g from top to bottom, wherein the partition plate 210a is located at a topmost layer, and the partition plate 210g is located at a bottommost layer. Servers are respectively arranged and disposed on the partition plates 210a to 210g. An extension baffle 230 extends from and is connected to the topmost-layer partition plate 210a. An outer side of the extension baffle 230 is connected with a power distributor 330a1, and an outer side of the topmost-layer partition plate 210a is connected with a power distributor 330a2. In addition, an outer side of the partition plate 210b is connected with a power distributor 330b, an outer side of the partition plate 210c is connected with a power distributor 330c, an outer side of the partition plate 210d is connected with a power distributor 330d, an outer side of the partition plate 210e is connected with a power distributor 330e, an outer side of the partition plate 210f is connected with a power distributor 330f, and an outer side of the partition plate 210g is not connected with a power distributor.

The servers arranged and disposed on the partition plate 210g are connected with the power distributor 330f at an upper layer, the servers arranged and disposed on the partition plate 210f are connected with the power distributor 330e at an upper layer, the servers arranged and disposed on the partition plate 210e are connected with the power distributor 330d at an upper layer, the servers arranged and disposed on the partition plate 210d are connected with the power distributor 330c at an upper layer, the servers arranged and disposed on the partition plate 210c are connected with the power distributor 330b at an upper layer, the servers arranged and disposed on the partition plate 210b are connected with the power distributor 330a2 at an upper layer, and the server arranged and disposed on the partition plate 210a is connected with the power distributor 330a1.

That is to say, the partition plates below the topmost-layer partition plate form “upper-to-lower” connection relationships, where a power distributor on an upper-layer partition plate is connected to the servers on a lower-layer partition plate, so that there is no need to mount a power distributor on the partition plate closest to the floor of the container body. This is not only convenient to operate, but also can reduce damage to the power distributors caused by moisture and stains in the container body 100 and the risk of short circuit.

In related technologies, each power distributor is provided with a switch to control power on or off. In some embodiments, the power distribution cabinet 310 is provided with a switch module for controlling each power distributor, and the switch module achieves independent control of each power distributor. For example, the switch module controls the power on or off of each power distributor. When a certain power distributor needs to be maintained or servers connected to a certain power distributor need to be powered off for maintenance, it is only necessary to use the switch module to power off the power of the power distributor alone, which facilitates maintenance and improves safety. Furthermore, since the switch modules are centrally provided in the distribution cabinet, centralized control of all the power distributors can be achieved, which is convenient for operation. For example, when it is necessary to turn off or turn on a plurality of power distributors, there is no need to separately approach each corresponding power distributors for operation. The partition plates on the layers of the rack 200 are, for example, made in a mesh structure so as to facilitate observation of the operating status of the servers on each partition layer.

As shown in FIG. 2, in order to enhance the overall strength of the rack 200, in an embodiment of the present application, the topmost-layer partition plate 210a and the extension baffle 230 are in a solid plate panel form, making it difficult for the staff to be promptly understand the operating status of the servers located on the topmost-layer partition plate 210a during maintenance. The nested container server apparatus of some embodiments of the present application further includes a top-layer apparatus status feedback means configured to feed back a top-layer apparatus status. The top-layer apparatus status feedback means is implemented in various ways such as software monitoring, hardware monitoring, remote monitoring and log monitoring.

In an embodiment of the present application, the top-layer apparatus status feedback means employs a reflective mirror observation means, which can achieve real-time monitoring of the server status by means of a status indicator light of the server itself without investing any software or hardware in the server. The reflective mirror observation means is connected to the server disposed on the corresponding topmost-layer partition plate 210a in the container body 100.

The number of the reflective mirror observation means is at least one, and each reflective mirror observation means corresponds to at least one server. For example, each reflective mirror observation means corresponds to one, two, or more servers, and the present application makes no limitation in this regard.

The reflective mirror observation means includes a plurality of feedback areas, each corresponding to at least one server disposed on the topmost-layer partition plate 210a for feeding back an operating status of the at least one server.

In other embodiments, the topmost-layer partition plate 210a and the extension baffle 230 may also be made into a mesh structure, facilitating the staff to monitor the status. In this case, the configuration of the top-layer apparatus status feedback means may be omitted.

In some embodiments, the server cluster container 1 includes a top partition plate and a top corrugated plate oppositely disposed, with a top wiring pipeline located between the top partition plate and the top corrugated plate. The top partition plate provides concealment and protection for the top wiring pipeline. In some embodiments, an upper side of the top partition plate is further provided with a heat-insulating layer for isolating external heat from entering an area below the top partition plate. The heat-insulating layer employs heat-insulating materials. Further, a foaming material, such as a polyurethane foaming material, is filled between the heat-insulating layer and the top corrugated plate to further enhance the heat insulation effect.

A method for mounting a nested container server apparatus of some embodiments of the present application includes the following steps:
unloading a container body 100 from a standard container 2;
mounting a plurality of servers on a rack 200; and
connecting the plurality of servers to an electric control system.

The method further includes taking a water curtain cooling structure fixedly stored in the container body 100 out from the container body, and mounting the water curtain cooling structure on an outer side of a dustproof mesh and/or a louver along a first side heat dissipation long side.

The method further includes unfolding an awning fixedly stored in the container body 100 and mounting the awning on tops of the first side heat dissipation long side 110, a second side heat dissipation long side 120, a first side short side 130 and a second side short side 140.

When required by the environment, the method further includes a step of pulling fans 910 of the cooling structure 900 out from inside of the container body 100 to outside of the container body, so that the fans 910 are placed outside.

In a specific embodiment of the present application, an outer dimension of the container body 100 of the nested container server apparatus is 5950 mm×2200 mm×2500 mm (L×W×H). It has 162 device sites for carrying the servers, with a total power of 700 kW, an input voltage of 380 V to 415 VAC, a frequency of 50/60 Hz, and a weight of less than 3 T, the certification standards including UL, CE, and CSA. The container body 100 is configured with two sets of racks, one set of power distribution cabinets, 14 sets of power distributors, eight negative pressure fans, two groups of louvers, two groups of wet curtains, 10 switches, and 162 terminal network cables.

In another specific embodiment of the present application, an outer dimension of the container body 100 of the nested container server apparatus is 11900 mm×2200 mm×2500 mm (L×W×H). It has 324 device sites for carrying the servers, with a total power of 700 kW*2, an input voltage of 380 V to 415 VAC, a frequency of 50/60 Hz, and a weight of less than 6 T, the certification standards including UL, CE, and CSA. The container body 100 is configured with four sets of racks, two set of power distribution cabinets, 28 sets of power distributors, 16 negative pressure fans, four groups of louvers, four groups of wet curtains, 20 switches, and 324 terminal network cables.

Of course, the present application may have many other embodiments. Those skilled in the art may make various corresponding changes and modifications according to the present application without departing from the spirit and essence of the present application, but these corresponding changes and modifications should all fall within the scope of protection of the attached claims of the present application.

### INDUSTRIAL APPLICABILITY

A nested container of the present application includes a container body, wherein an outer contour dimension of the container body is smaller than an inner space dimension of a standard container, and the container body is configured to be entirely loaded into the standard container. When the container body is loaded within the standard container, a first gap and/or a second gap are respectively present between left and right side walls of the container body along a length direction and left and right inner walls of the standard container along the length direction. A nested container server apparatus of the present application includes a plurality of servers and the aforementioned nested container, wherein the servers are arranged and disposed on the rack and connected to the electric control system. The present application ensures the safety and stability of transportation while maximizing integration, and greatly reduces the damage rate during transportation.

1. A nested container, comprising a container body, wherein an outer contour dimension of the container body is smaller than an inner space dimension of a standard container, and the container body is configured to be entirely loaded into the standard container.

2. The nested container of claim 1, wherein when the container body is loaded within the standard container, a first gap and/or a second gap are respectively present between left and right side walls of the container body along a length direction and left and right inner walls of the standard container along the length direction;
wherein a sum of the first gap and the second gap is 90±20 mm.

3. (canceled)

4. The nested container of claim 2, wherein a third gap and/or a fourth gap are respectively present between front and rear side walls of the container body along a width direction and front and rear inner walls of the standard container along the width direction;
wherein a sum of the third gap and the fourth gap is 90±20 mm;
wherein a fifth gap is present between a top wall of the container body and a top inner wall of the standard container; and
wherein the fifth gap is 40±10 mm.

5-7. (canceled)

8. The nested container of claim 4, further comprising a buffer member disposed in at least one of the first gap to the fifth gap;
wherein the buffer member comprises a corner protection structural member mounted on a corner member of the container body;
wherein the buffer member comprises a ridge structural member mounted to at least one of a corner post, a bottom side beam, and a top side beam of the container body;
wherein the nested container further comprises a limiting member disposed in at least one of the first gap to the fifth gap;
wherein the limiting member comprises left and right side limiting structural members disposed in the first gap and/or the second gap and disposed along the length direction of the standard container; and
wherein the limiting member comprises front and rear side limiting structural members disposed in the third gap or the fourth gap away from an entrance of the standard container.

9-13. (canceled)

14. The nested container of claim 1, wherein a movement assisting accessory is disposed between a bottom of the container body and a bottom of the standard container to facilitate movement;
wherein the movement assisting accessory comprises a roller means connected to the bottom of the container body; and
wherein the roller means is connected to a bottom of the bottom side beam and/or the corner member of the container body.

15-18. (canceled)

19. The nested container of claim 14, wherein the movement assisting accessory comprises a slide rail means connected to the bottom of the container body or to a bottom plate of the standard container.

20. The nested container of claim 14, wherein the movement assisting accessory comprises a slide plate means connected to the bottom of the container body or to a bottom plate of the standard container.

21. The nested container of claim 1, wherein at least one container body is loaded within the standard container along a length direction of the container body;
wherein the container body comprises a corner member; and
wherein the nested container further comprises a tensioning member connected between the corner member and an inner wall of the standard container.

22-23. (canceled)

24. A nested container, comprising a container body, a rack, and an electric control system, wherein the rack and the electric control system are respectively fixed within the container body, an outer contour dimension of the container body is smaller than an inner space dimension of a standard container, and the container body is configured to be entirely loaded into the standard container.

25. The nested container of claim 24, wherein when the container body is loaded within the standard container, a first gap and/or a second gap are respectively present between left and right side walls of the container body along a length direction and left and right inner walls of the standard container along the length direction;
wherein a sum of the first gap and the second gap is 90±20 mm.

26. (canceled)

27. The nested container of claim 25, wherein a third gap and/or a fourth gap are respectively present between front and rear side walls of the container body along a width direction and front and rear inner walls of the standard container along the width direction;
wherein a sum of the third gap and the fourth gap is 90±20 mm;
wherein a fifth gap is present between a top wall of the container body and a top inner wall of the standard container; and
wherein the fifth gap is 40±10 mm.

28-30. (canceled)

31. The nested container of claim 27, further comprising a buffer member disposed in at least one of the first gap to the fifth gap;
wherein the buffer member comprises a corner protection structural member mounted on a corner member of the container body;
wherein the buffer member comprises a ridge structural member mounted to at least one of a corner post, a bottom side beam, and a top side beam of the container body;
wherein the nested container further comprises a limiting member disposed in at least one of the first gap to the fifth gap;
wherein the limiting member comprises left and right side limiting structural members disposed in the first gap and/or the second gap and disposed along the length direction of the standard container; and
wherein the limiting member comprises front and rear side limiting structural members disposed in the third gap or the fourth gap away from an entrance of the standard container.

32-36. (canceled)

37. The nested container of claim 24, wherein a movement assisting accessory is disposed between a bottom of the container body and a bottom of the standard container to facilitate movement;
wherein the movement assisting accessory comprises a roller means connected to the bottom of the container body; and
wherein the roller means is connected to a bottom of the bottom side beam and/or the corner member of the container body.

38-41. (canceled)

42. The nested container of claim 37, wherein the movement assisting accessory comprises a slide rail means connected to the bottom of the container body or to a bottom plate of the standard container.

43. The nested container of claim 37, wherein the movement assisting accessory comprises a slide plate means connected to the bottom of the container body or to a bottom plate of the standard container.

44. The nested container of claim 24, wherein the container body comprises a corner member;
wherein at least one container body is loaded within the standard container along a length direction of the container body; and
wherein the nested container further comprises an accessory box fixed within the container body.

45. (canceled)

46. The nested container of claim 24, wherein the electric control system comprises a power distribution cabinet, and racks are symmetrically disposed on both sides of the power distribution cabinet;
wherein the container body comprises a first side heat dissipation long side and a second side heat dissipation long side oppositely disposed, the first side heat dissipation long side is provided with a dustproof mesh and/or a louver, and the second side heat dissipation long side is provided with a cooling structure;
wherein a position on the first side heat dissipation long side corresponding to the power distribution cabinet is provided with a protective wall, and a position on the first side heat dissipation long side corresponding to the rack is provided with a dustproof mesh and/or a louver; and
wherein the nested container further comprises a water curtain cooling structure and a water curtain storage structure configured to storing the water curtain cooling structure, wherein the water curtain storage structure is located within the container body.

47. (canceled)

48. The nested container of claim 46, wherein the cooling structure comprises a fan and a fan mounting frame, and the fan is mounted to the container body via the fan mounting frame;
wherein the fan mounting frame comprises a connection frame connected to the container body and a support frame detachably connected to an inner side or an outer side of the connection frame via a plurality of fasteners, and the fan is disposed on the support frame;
wherein the connection frame is further partially connected to at least one of the top side beam, the bottom side beam, and the corner post of the container body;
wherein the support frame comprises a fixing portion configured to detachably connect the connection frame via the fasteners and a support portion configured to support the fan;
wherein the support frame comprises a limiting portion configured to limit displacement of the fan;
wherein the support frame is made from a metal sheet that is bent and processed to form the fixing portion, the support portion and the limiting portion.

49-57. (canceled)

58. A nested container server apparatus, comprising a plurality of servers, wherein the nested container server apparatus further comprises the nested container of claim 24, and the servers are arranged and disposed on the rack and connected to the electric control system.

59. The nested container server apparatus of claim 58, wherein the top of the rack has a topmost-layer partition plate and an extension baffle extending horizontally from the topmost-layer partition plate, and the servers are disposed on the topmost-layer partition plate and/or the extension baffle;
wherein the nested container server apparatus further comprises a top-layer apparatus status feedback means configured to feed back an operating status of the servers on the topmost-layer partition plate and/or the extension baffle;
wherein the top-layer apparatus status feedback means is a reflective mirror observation means; and
wherein the reflective mirror observation means comprises a plurality of feedback areas, each corresponding to at least one of the servers disposed on the topmost-layer partition plate and/or the extension baffle.

60-62. (canceled)
